(19) United States
(12) Patent Application Publication
(10) Pub. No.: US 2017/0287834 A1
(43) Pub. Date: Oct. 5, 2017

(54) Contact Expose Etch Stop

(71) Applicant: Microchip Technology Incorporated, Chandler, AZ (US)

(72) Inventors: Dan Grimm, Mesa, AZ (US); Gregory Dix, Tempe, AZ (US); Rodney Schroeder, Phoenix, AZ (US)

(73) Assignee: Microchip Technology Incorporated, Chandler, AZ (US)

(21) Appl. No.: 15/471,634

(22) Filed: Mar. 28, 2017

Related U.S. Application Data
(60) Provisional application No. 62/314,862, filed on Mar. 29, 2016.

(51) Int. Cl. H01L 23/535; H01L 29/06; H01L 23/00; H01L 27/088; H01L 25/00; H01L 21/768; H01L 21/8234; H01L 29/417; H01L 25/065

(52) U.S. Cl. CPC H01L 23/535; H01L 29/41758; H01L 29/0649; H01L 24/48; H01L 25/0655; H01L 25/50; H01L 21/76895; H01L 21/823475; H01L 27/088; H01L 2225/06582; H01L 2225/06506

(57) ABSTRACT

The present disclosure relates to semiconductor devices and the teachings thereof may be embodied in metal oxide semiconductor field effect transistors (MOSFET). Some embodiments may include a power MOSFET with transistor cells, each cell comprising a source and a drain region; a first dielectric layer disposed atop the transistor cells; a silicon rich oxide layer on the first dielectric layer; grooves through the multi-layered dielectric, each groove above a respective source or drain region and filled with a conductive material; a second dielectric layer atop the multi-layered dielectric; openings in the second dielectric layer, each opening exposing a contact area of one of the plurality of grooves; and a metal layer disposed atop the second dielectric layer and filling the openings. The metal layer may form at least one drain metal wire and at least one source metal wire. The at least one drain metal wire may connect two drain regions through respective grooves. The at least one source metal wire may connect two source regions through respective grooves. Each groove has a length extending from the at least one drain metal wire to the at least one source metal wire in an adjacent pair.

### RELATED PATENT APPLICATION

This application claims priority to U.S. Provisional Patent Application No. 62/314,862 filed Mar. 29, 2016; which is hereby incorporated by reference herein for all purposes.

### TECHNICAL FIELD

The present disclosure relates to semiconductor devices and the teachings thereof may be embodied in metal oxide semiconductor field effect transistors (MOSFET).

### BACKGROUND

Power MOSFETs include metal wires deposited to connect source elements to one another and to connect drain elements to one another, usually in parallel. Typically, a metal film is deposited over a dielectric layer on a semiconductor wafer. The metal film is patterned and etched to leave the required metal wires. The metal wires make contact with various active areas (e.g., the drain areas, source areas, and/or gates) using vias. Vias are holes previously etched in the dielectric layer then filled with a conductor such as tungsten (e.g., using chemical vapor deposition or CVD). For more complicated connections, additional layers of metal may be separated by additional insulating layers and connected to one another by further vias therethrough. U.S. Pat. No. 8,937,351 entitled “Power MOS Transistor with Improved Metal Contact” relates to MOSFETs and is hereby incorporated by reference in its entirety.

FIG. 1 is a sectional view showing a prior art MOSFET 100a. MOSFET 100a includes an epitaxial layer 150 comprising drain regions 170 and source regions 180. An oxide layer 160 is deposited atop the epitaxial layer 150. The oxide layer 160 includes a plurality of vias or grooves 130a, 130b filled with a conducting material providing electrical contact from the drain and source regions 170, 180 to respective metal 110. The sectional view of FIG. 1 is taken in a plane that shows only drain metal 110a.

As shown in FIG. 1, an additional oxide layer 140 has been deposited and patterned to provide openings 120a. The openings 120a are filled with the metal layer 110a during another step in the process. This provides electrical contact through grooves 130a to reach drains 170. In a different section, the additional oxide layer 140 is patterned to provide openings 120 allowing a source layer of metal to make electrical contact through grooves 130b to sources 180.

FIG. 2 is a sectional view showing a prior art MOSFET 100b, showing the results of an inaccurate process step to etch the openings 120a. According to the prior art, it is difficult to stop the etch process accurately at the boundary between oxide layer 160 and additional oxide layer 140. As shown in FIG. 2, over-etching results in openings 120a that extend beyond the top of grooves 130a and extend into oxide layer 160.

### SUMMARY

The teachings of the present disclosure may be used to provide a more dependable etch stop for manufacturing a MOSFET. Various embodiments may include a multi-layer dielectric comprised of standard oxide and silicon rich oxide (SRO). The contact etch process may be more reliable because the SRO offers a more effective etch stop.

For example, some embodiments may include a power metal-oxide-semiconductor field effect transistor (MOSFET) comprising a plurality of transistor cells, each cell comprising a source region and a drain region disposed on a silicon wafer die; a first dielectric layer disposed on the surface of the silicon wafer die atop the plurality of transistor cells; a silicon rich oxide layer disposed on the first dielectric layer forming a multi-layered dielectric; a plurality of grooves through said multi-layered dielectric layer, each groove disposed above a respective source region or drain region of a cell and filled with a conductive material; a second dielectric layer disposed atop the multi-layered dielectric layer; openings in the second dielectric layer, each opening exposing a contact area of one of the plurality of grooves; and a metal layer disposed atop the second dielectric layer and filling the openings. The metal layer may form at least one drain metal wire and at least one source metal wire. The at least one drain metal wire may connect two drain regions of the plurality of transistor cells through respective grooves disposed above the two drain regions. The at least one source metal wire may connect two source regions of the plurality of transistor cells through respective grooves disposed above the at least two source regions. Each groove has a length extending from the at least one drain metal wire to the at least one source metal wire in an adjacent pair.

In some embodiments, each drain region and each source region is strip shaped.

In some embodiments, each groove covers a substantial surface area of the respective drain region or the respective source region.

In some embodiments, each groove may be associated with exactly one of the openings in the second dielectric layer.

In some embodiments, the openings in said second dielectric layer have approximately square or round shapes.

In some embodiments, the openings in said second dielectric layer have approximately rectangular shapes.

In some embodiments, no additional metal layer is disposed on top of the metal layer.

Some embodiments may include a device comprising a microcontroller; and at least one power metal-oxide-semiconductor field effect transistor (MOSFET) comprising a plurality of transistor cells. Each transistor cell may include: a source region and a drain region disposed on a silicon wafer die; a first dielectric layer disposed on the surface of the silicon wafer die atop the plurality of transistor cells; a silicon rich oxide layer disposed on the first dielectric layer forming a multi-layered dielectric; a plurality of grooves through said multi-layered dielectric layer, each groove disposed above a respective source region or drain region of a cell and filled with a conductive material; a second dielectric layer disposed atop the multi-layered dielectric layer; and openings in the second dielectric layer, each opening exposing a contact area of one of the plurality of grooves; a metal layer disposed atop the second dielectric layer and filling the openings. The metal layer may form at least one drain metal wire and at least one source metal wire. The at least one drain metal wire may connect two drain regions of the plurality of transistor cells through respective grooves disposed above the two drain regions. The at least one source metal wire may connect two source regions of the plurality of transistor cells through respective grooves disposed above the at least two source regions. Each groove may have a length extending from the at least one drain metal wire to the at least one source metal wire in an adjacent pair.

Some embodiments may include a housing; a first chip having the microcontroller formed thereon; and a second chip having the at least one power transistor formed thereon. The first and second chip may be connected within the housing by wire bonding.

Some embodiments may include a single chip having the microcontroller and the at least one power MOSFET formed thereon.

Some embodiments may include a plurality of power MOSFETs.

In some embodiments, the drain region and the source region may have strip shapes.

In some embodiments, each groove may cover a substantial surface area of the respective drain region or the respective source region.

In some embodiments, each groove may be associated with exactly one of the openings in the second dielectric layer.

In some embodiments, the openings in said second dielectric layer may have approximately square or round shapes.

In some embodiments, the openings in said second dielectric layer may have approximately rectangular shapes.

In some embodiments, no additional metal layer is disposed on top of the metal layer.

Some embodiments may include methods for forming a device including a power metal-oxide-semiconductor field effect transistor (MOSFET). The methods may include: forming a plurality of transistor cells on a silicon wafer die, each cell comprising a source region and a drain region; depositing a first dielectric layer on the surface of the silicon wafer die atop the plurality of transistor cells; depositing a silicon rich oxide layer on the first dielectric layer forming a multi-layered dielectric therewith; defining a plurality of grooves through said multi-layered dielectric layer, each groove disposed above a respective source region or drain region of a cell; filling each groove with a conductive material; depositing a second dielectric layer disposed atop the multi-layered dielectric layer; etching openings in the second dielectric layer, each opening exposing a contact area of one of the plurality of grooves; and depositing a metal layer atop the second dielectric layer thereby filling the openings. The metal layer may form at least one drain metal wire and at least one source metal wire. The at least one drain metal wire may connect two drain regions of the plurality of transistor cells through respective grooves disposed above the two drain regions. The at least one source metal wire may connect two source regions of the plurality of transistor cells through respective grooves disposed above the at least two source regions. Each groove may have a length extending from the at least one drain metal wire to the at least one source metal wire in an adjacent pair.

Some embodiments may include forming the power MOSFET on a first chip and connecting the first chip to a second chip comprising a microcontroller by wire bonding.

Some embodiments may include forming the power MOSFET on a chip having a microcontroller formed thereon.

### BRIEF DESCRIPTION OF THE DRAWINGS

The various embodiments of these teachings may be better understood with reference to the following figures:

FIG. 1 is a sectional view showing a prior art MOSFET;

FIG. 2 is a sectional view showing a prior art MOSFET;

FIG. 3 is a sectional view showing an example MOSFET incorporating the teachings of the present disclosure;

FIG. 4 is a top view showing a device including an example MOSFET incorporating the teachings of the present disclosure;

FIGS. 5A and 5B are electrical schematic drawings showing an example device formed on a single chip incorporating the teachings of the present disclosure;

FIG. 6 is an electrical schematic drawing showing an example device formed on two chips incorporating the teachings of the present disclosure; and

FIG. 7 is a flowchart showing an example method for manufacturing a MOSFET incorporating teachings of the present disclosure.

### DETAILED DESCRIPTION

The teachings of the present disclosure may be used in the design and/or manufacture of MOSFETs. In some embodiments, depositing a multilayer dielectric comprised of both a standard oxide and a silicon rich oxide (SRO) provides an etch stop for the contact expose etch. Selection of etch chemistry allows etching a standard oxide selective to SRO (e.g., the etch will remove the standard oxide without removing SRO). An example etch chemistry may include a mixed gas (e.g., C5F8/O2/Ar).

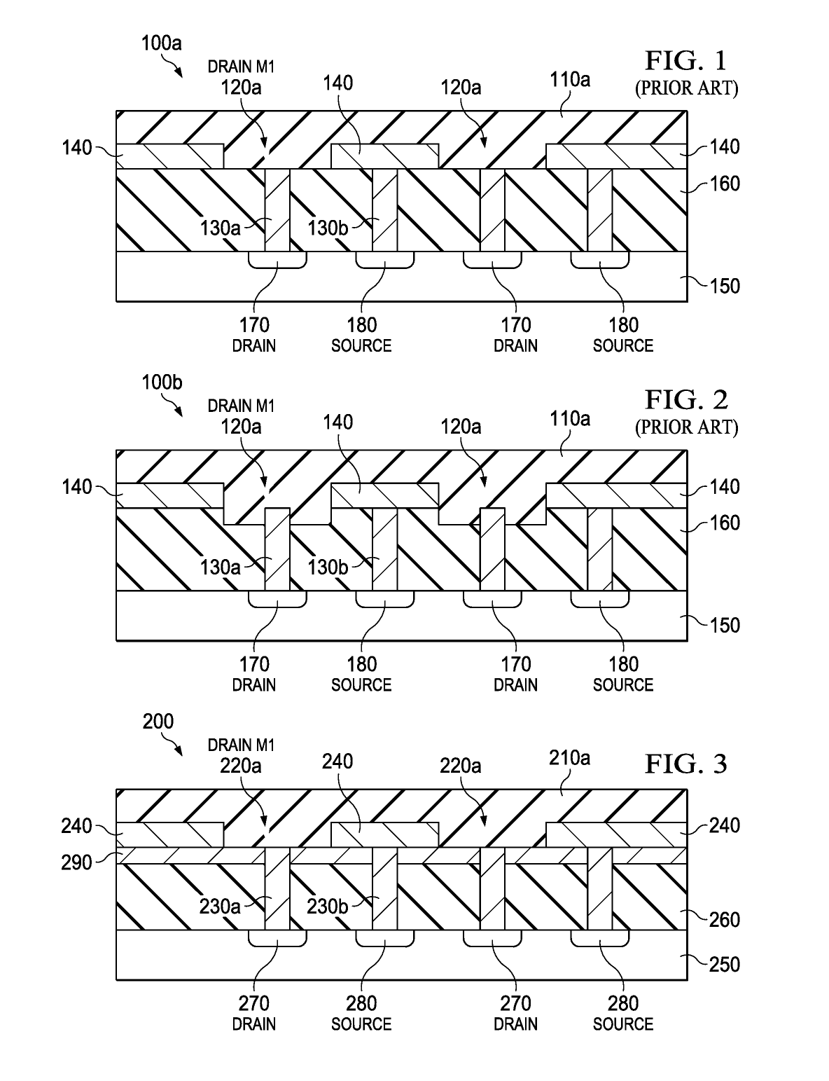

FIG. 3 is a sectional view showing an example MOSFET 200 incorporating the teachings of the present disclosure. As shown in FIG. 3, MOSFET 200 includes a composite layer of dielectric made of standard oxide 260 topped by SRO (Silicon Rich Oxide) 290. Oxide 240 may also be referred to as a protective contact oxide. A mixed gas such as C5F8/O2/Ar may etch the oxide 240 with very good selectivity to the SRO 290. In contrast to the MOSFET 100 shown in FIG. 2, the risk of over-etching is reduced because of the presence of the effective etch stop at SRO 290.

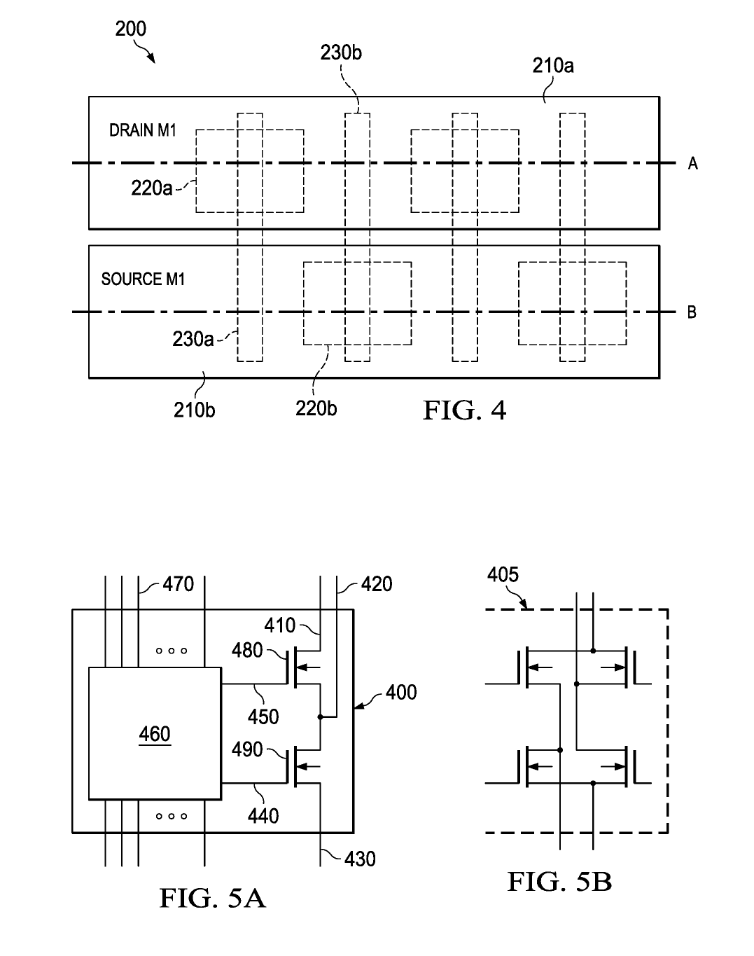

FIG. 4 is a top view showing example power MOSFET 200 incorporating the teachings of the present disclosure. As shown in FIG. 4, the active drain and source regions are connected to one another with contact grooves 220a and 220b, respectively. Contact grooves 220 are formed within the dielectric layer 260 deposited on the surface top of semiconductor wafer 250 (e.g., a silicon wafer). The grooves 220 may be formed to connect the respective active source 280 and drain areas 270. Similar contact grooves can be used for gate connections. However, FIGS. 3 and 4 only show the connections to the drain and source regions. Once formed through the oxide layer 260, the grooves 220 are filled with a conducting material (e.g., tungsten).

The MOSFET 200 comprises a semiconductor die including an epitaxial layer 250 with active drain regions 270 and source regions 280. The regions 270 and 280 are generally arranged in an alternating pattern creating a plurality of transistor cells each having a source, a drain, and a respective gate (not shown explicitly). The drain regions 270 and source regions 280 may have various forms and/or shapes. In the embodiment shown in FIG. 3, the drain regions 270 and the source regions 280 comprise elongated strips. However, other shapes may be used.

To create a power MOSFET, a plurality of these cells are connected in parallel. In such an embodiment, all drain regions 270 are connected to each other and all source regions 280 are connected to each other. The teachings of the present disclosure may be used to create these connections. To begin, a dielectric layer 260 is deposited on the top surface of the epitaxial layer 250. A silicon rich oxide (SRO) layer 290 is deposited on the top surface of the epitaxial layer 250. The combination of the dielectric layer 260 and the SRO layer 290 make up a multilayer dielectric. The multilayer dielectric may then be patterned and etched to create grooves 230a and 230b positioned above the drain regions 270 and source regions 280, respectively. The etched grooves 230a, 230b may then be filled with a conducting material, such as tungsten. The contact etch may be a typical etch with the same etch rate for both the standard dielectric layer 260 and the SRO layer 290.

In some embodiments, a second dielectric layer 240 is deposited on the grooved multilayer dielectric. This second dielectric layer 240 may then be patterned and etched to form specific contact openings 220a and 220b. In the example shown in FIGS. 3 and 4, contact openings 220a are formed above each of the drain regions 270 and contact openings 220b are formed above each of the source regions 280. This etch process reaches an effective stop against the SRO layer 290 and, therefore, reduces the risk of over-etching the openings down into the dielectric layer 260. As discussed above, selection of etch chemistry allows etching a standard oxide selective to SRO (e.g., the etch will remove the standard oxide without removing SRO). An example etch chemistry may include a mixed gas (e.g., C5F8/O2/Ar).

As shown in FIGS. 3 and 4, a metal layer 210 is deposited on the structure after the openings 220 are created. Metal layer 210 provides the respective interconnection of drain regions 270 and source regions 180 to one another. The top metal layer 210 may be patterned and etched to form single insulated wire lines 210a, 210b as shown in the top view of FIG. 4.

In some embodiments as mentioned above, the drain regions 270 and source regions 280 may have strip shapes as shown in FIG. 4. The grooves 230 may cover a substantial surface area of the underlying drain regions 270 and source regions 280, respectively, for example more than 50%, more than 75%, or more than 90%. Each groove 230 may be associated with one opening 220 in the dielectric layer 240 as shown in FIGS. 3 and 4. However, in some embodiments, more than one contact opening 220 may be provided in the second dielectric insulating layer 240.

The openings 220 in the second dielectric layer 240 may have rectangular shapes as shown in FIG. 4. However, in some embodiments, the openings 220 in the second dielectric layer 240 may have approximately square or round shapes.

Additional layers of metal and corresponding via openings can be added to enable metal wire widths suitable for assembly of the part. The openings 220 may be large enough for the metal to directly contact the tungsten of groove 230 thus eliminating the need for a separate via filling step while maintaining a substantially tight spacing of the tungsten layer. Metal wires 210a, b may comprise aluminum and/or copper. Dielectric layers 240 and 260 may comprise any type of dielectric oxide layer.

FIGS. 5A and 5B are electrical schematic drawings showing example devices formed on a single chip 400 incorporating the teachings of the present disclosure. The device may include a microcontroller 460 combined with two power transistors 480 and 490 or microcontroller 460 combined with an H-Bridge 405. Microcontroller 460 may include a plurality of peripheral devices such as controllable drivers, modulators, in particular pulse width modulators, timers, etc. and may drive gates 440 and 450 of transistors 480 and 490 directly or through respective additional drivers. The chip 400 may make a plurality of functions of the microcontroller 460 available through external connections or pins 470. The source of first transistor 480 can be connected to external connection or pin 410. Similarly, external connection 420 may include a connection to the combined drain and source of transistors 480 and 490 and external connection and/or pin 430 for the drain of the second transistor 430. Other transistor structures manufactured in accordance with the embodiments of the present disclosure can be used (e.g., an H-bridge or multiple single transistors). FIG. 5B shows an exemplary plurality of MOSFETs connected to form an H-Bridge that can be coupled with a microcontroller 460 or modulator within a single semiconductor chip 405.

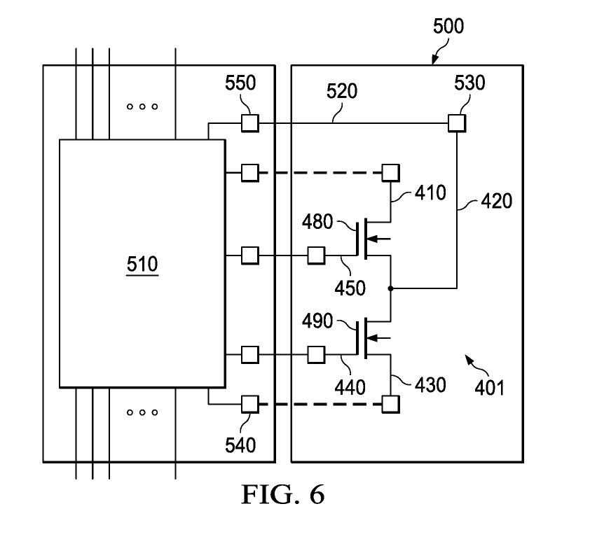

FIG. 6 is an electrical schematic drawing showing an example device formed on two chips incorporating the teachings of the present disclosure. The device may include two separate semiconductor chips that can be combined within a single housing. A first chip 540 may comprise a microcontroller 510 and a plurality of bond pads 550. The second chip 500 may comprise one or more power MOSFETs 401 as described above, as well as various bond pads 530. The two chips 500 and 540 may be connected by bond wires 520. Dotted lines indicate connections to the power MOSFET devices 401 not connected to the controller chip 540. The resulting device may include external connections provided by a lead frame as known in the art.

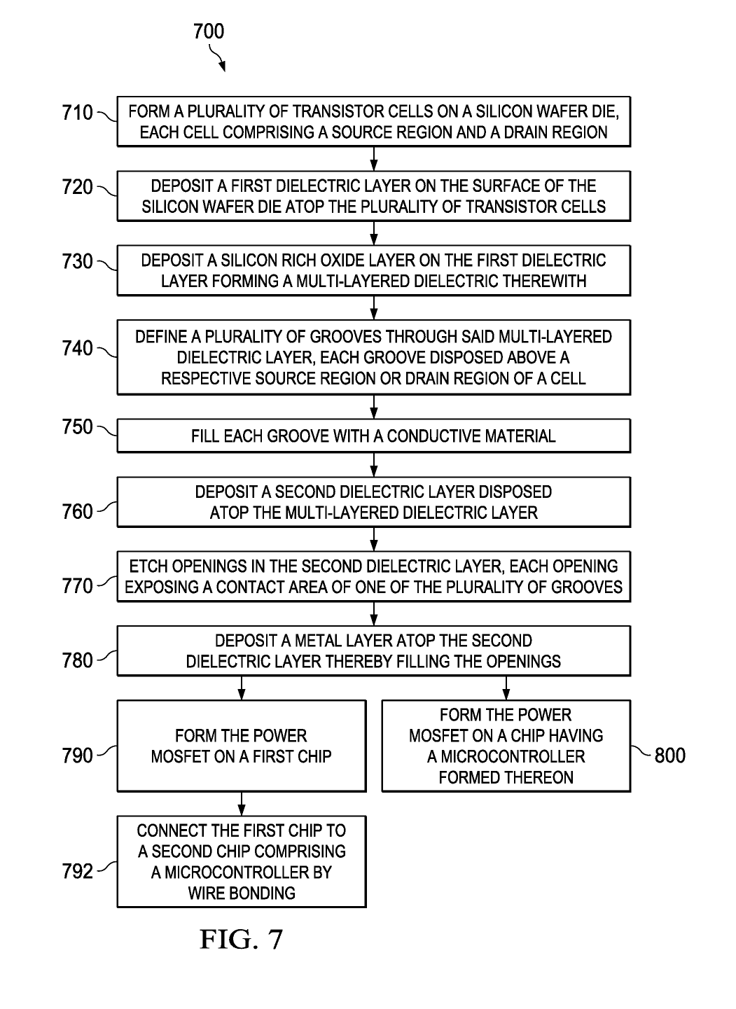

FIG. 7 is a flowchart showing an example method 700 for manufacturing a MOSFET incorporating teachings of the present disclosure.

Method 700 may include Step 710, forming a plurality of transistor cells on a silicon wafer die 250, each cell comprising a source region 280 and a drain region 270.

Method 700 may include Step 720, depositing a first dielectric layer 260 on the surface of the silicon wafer die 250 atop the plurality of transistor cells 270/280.

Method 700 may include Step 730, depositing a silicon rich oxide layer 290 on the first dielectric layer 260 forming a multi-layered dielectric therewith.

Method 700 may include Step 740, defining a plurality of grooves 230 through said multi-layered dielectric layer 260, each groove 230 disposed above a respective source region 280 or drain region 270 of a cell.

Method 700 may include Step 750, filling each groove 230 with a conductive material.

Method 700 may include Step 760, depositing a second dielectric layer 240 atop the multi-layered dielectric layer 260/290.

Method 700 may include Step 770, etching openings 220 in the second dielectric layer 240, each opening 220 exposing a contact area of one of the plurality of grooves 230.

Method 700 may include Step 780, depositing a metal layer 210 atop the second dielectric layer 240 thereby filling the openings 220.

Method 700 may include Step 790, forming the power MOSFET 200 on a first chip 500.

Method 700 may include Step 792, connecting the first chip 500 to a second chip 540 comprising a microcontroller 510 by wire bonding.

Method 700 may include Step 800, forming the power MOSFET 200 on a chip 400 having a microcontroller 460 formed thereon.

1. A power metal-oxide-semiconductor field effect transistor (MOSFET) comprising:
a plurality of transistor cells, each cell comprising a source region and a drain region disposed on a silicon wafer die;
a first dielectric layer disposed on the surface of the silicon wafer die atop the plurality of transistor cells;
a silicon rich oxide layer disposed on the first dielectric layer forming a multi-layered dielectric;
a plurality of grooves through said multi-layered dielectric layer, each groove disposed above a respective source region or drain region of a cell and filled with a conductive material;
a second dielectric layer disposed atop the multi-layered dielectric layer;
openings in the second dielectric layer, each opening exposing a contact area of one of the plurality of grooves; and
a metal layer disposed atop the second dielectric layer and filling the openings;
wherein the metal layer forms at least one drain metal wire and at least one source metal wire;
the at least one drain metal wire connects two drain regions of the plurality of transistor cells through respective grooves disposed above the two drain regions;
the at least one source metal wire connects two source regions of the plurality of transistor cells through respective grooves disposed above the at least two source regions; and
each groove has a length extending from the at least one drain metal wire to the at least one source metal wire in an adjacent pair.

2. A power MOSFET according to claim 1, wherein each drain region and each source region is strip shaped.

3. A power MOSFET according to claim 1, further comprising each groove covering more than 50% of a surface area of the respective drain region or the respective source region.

4. A power MOSFET according to claim 1, further comprising each groove associated with exactly one of the openings in the second dielectric layer.

5. A power MOSFET according to claim 1, further comprising the openings in said second dielectric layer having approximately square or round shapes.

6. A power MOSFET according to claim 1, further comprising the openings in said second dielectric layer having approximately rectangular shapes.

7. A power MOSFET according to claim 1, wherein no additional metal layer is disposed on top of the metal layer.

8. A device comprising:
a microcontroller; and
at least one power metal-oxide-semiconductor field effect transistor (MOSFET) comprising a plurality of transistor cells, each cell comprising:
a source region and a drain region disposed on a silicon wafer die;
a first dielectric layer disposed on the surface of the silicon wafer die atop the plurality of transistor cells;
a silicon rich oxide layer disposed on the first dielectric layer forming a multi-layered dielectric;
a plurality of grooves through said multi-layered dielectric layer, each groove disposed above a respective source region or drain region of a cell and filled with a conductive material;
a second dielectric layer disposed atop the multi-layered dielectric layer;
openings in the second dielectric layer, each opening exposing a contact area of one of the plurality of grooves; and
a metal layer disposed atop the second dielectric layer and filling the openings;
wherein the metal layer forms at least one drain metal wire and at least one source metal wire;
the at least one drain metal wire connects two drain regions of the plurality of transistor cells through respective grooves disposed above the two drain regions;
the at least one source metal wire connects two source regions of the plurality of transistor cells through respective grooves disposed above the at least two source regions; and
each groove has a length extending from the at least one drain metal wire to the at least one source metal wire in an adjacent pair.

9. A device according to claim 8, further comprising a housing;
a first chip having the microcontroller formed thereon; and
a second chip having the at least one power transistor formed thereon;
wherein the first and second chip are connected within the housing by wire bonding.

10. A device according to claim 8, further comprising a single chip having the microcontroller and the at least one power MOSFET formed thereon.

11. A device according to claim 8, further comprising a plurality of power MOSFETs.

12. A device according to claim 8, further comprising the drain region and the source region having strip shapes.

13. A device according to claim 8, further comprising each groove covering more than 50% of a surface area of the respective drain region or the respective source region.

14. A device according to claim 8, further comprising each groove associated with exactly one of the openings in the second dielectric layer.

15. A device according to claim 14, further comprising the openings in said second dielectric layer having approximately square or round shapes.

16. A device according to claim 14, further comprising the openings in said second dielectric layer having approximately rectangular shapes.

17. The device according to claim 8, wherein no additional metal layer is disposed on top of the metal layer.

18. A method for forming device including a power metal-oxide-semiconductor field effect transistor (MOSFET), the method comprising:
forming a plurality of transistor cells on a silicon wafer die, each cell comprising a source region and a drain region;
depositing a first dielectric layer on the surface of the silicon wafer die atop the plurality of transistor cells;
depositing a silicon rich oxide layer on the first dielectric layer forming a multi-layered dielectric therewith;
defining a plurality of grooves through said multi-layered dielectric layer, each groove disposed above a respective source region or drain region of a cell;
filling each groove with a conductive material;
depositing a second dielectric layer disposed atop the multi-layered dielectric layer;
etching openings in the second dielectric layer, each opening exposing a contact area of one of the plurality of grooves; and
depositing a metal layer atop the second dielectric layer thereby filling the openings;
wherein the metal layer forms at least one drain metal wire and at least one source metal wire;
the at least one drain metal wire connects two drain regions of the plurality of transistor cells through respective grooves disposed above the two drain regions;
the at least one source metal wire connects two source regions of the plurality of transistor cells through respective grooves disposed above the at least two source regions; and
each groove has a length extending from the at least one drain metal wire to the at least one source metal wire in an adjacent pair.

19. A method according to claim 18, further comprising:
forming the power MOSFET on a first chip; and
connecting the first chip to a second chip comprising a microcontroller by wire bonding.

20. A method according to claim 20, further comprising forming the power MOSFET on a chip having a microcontroller formed thereon.
